(19) United States
(12) Patent Application Publication
(10) Pub. No.: US 2013/0062609 A1
(43) Pub. Date: Mar. 14, 2013

(54) III-N FET ON SILICON USING FIELD SUPPRESSING REO

(71) Applicants: Robin Smith, Palo Alto, CA (US); David Williams, Menlo Park, CA (US); Rytis Dargis, Fremont, CA (US); Michael Lebby, Apache Junction, AZ (US)

(72) Inventors: Robin Smith, Palo Alto, CA (US); David Williams, Menlo Park, CA (US); Rytis Dargis, Fremont, CA (US); Michael Lebby, Apache Junction, AZ (US)

(21) Appl. No.: 13/232,059

(22) Filed: Sep. 14, 2011

(51) Int. Cl. H01L 29/12; H01L 21/20; H01L 29/02

(52) U.S. Cl. 257/76; 257/190; 438/479; 257/E29.068; 257/E29.002; 257/E21.09

(57) ABSTRACT

A III-N on silicon substrate with enhanced breakdown voltage including a rare earth oxide structure deposited on the silicon substrate and a layer of single crystal III-N semiconductor material deposited on the rare earth oxide structure. The rare earth oxide has a dielectric constant greater (approximately twice) than the III-N semiconductor material. The rare earth oxide structure is selected to cooperate with the layer of single crystal III-N semiconductor material to reduce the thickness of the layer of single crystal III-N semiconductor material required for a selected breakdown voltage to a value less than a thickness of the layer of single crystal III-N semiconductor material for the selected breakdown voltage without the cooperating single crystal rare earth oxide.

### FIELD OF THE INVENTION

This invention relates in general to the deposition of III-N layers on silicon wafers and the fabrication of FETs on the III-N in switching circuits.

### BACKGROUND OF THE INVENTION

It has been found that III-N layers, e.g. GaN, on silicon substrates are a desirable semiconductor material in many switching applications. However, as desired operating voltages for electric switching increase, the thickness of the III-N layer has to be increased to prevent breakdown occurring in the silicon substrate. Mechanically thick III-N on a silicon substrate is a challenge since the III-N layer tends to crack and the induced wafer bow can make it very difficult to process the wafer.

It would be highly advantageous, therefore, to remedy the foregoing and other deficiencies inherent in the prior art.

Accordingly, it is an object of the present invention to provide new and improved methods of fabricating FETs on layers of III-N on silicon substrates.

It is another object of the present invention to provide new and improved methods of fabricating FETs on layers of III-N on silicon substrates using rare earth oxide layers for field suppressing.

It is another object of the present invention to provide new and improved FETs on layers of III-N on silicon substrates for high power switching.

### SUMMARY OF THE INVENTION

Briefly, to achieve the desired objects and aspects of the instant invention in accordance with a preferred embodiment thereof, provided is a III-N on silicon wafer with enhanced breakdown voltage including a crystalline silicon substrate, a rare earth oxide structure deposited on the silicon substrate and including at least one layer of single crystal rare earth oxide, and a layer of single crystal III-N semiconductor material deposited on the rare earth oxide structure. The rare earth oxide has a dielectric constant greater (close to or approximately two times greater) than the III-N semiconductor material, and the at least one layer of single crystal rare earth oxide is selected to cooperate with the layer of single crystal III-N semiconductor material to reduce the thickness of the layer of single crystal III-N semiconductor material required for a selected breakdown voltage to a value less than a thickness of the layer of single crystal III-N semiconductor material for the selected breakdown voltage without the cooperating at least one layer of single crystal rare earth oxide.

The desired objects and aspects of the instant invention are further realized in accordance with a specific embodiment of a field effect transistor (FET) fabricated on a III-N on silicon substrate with enhanced breakdown voltage. The FET includes a crystalline silicon substrate, a rare earth oxide structure deposited on the silicon substrate and including at least one layer of single crystal rare earth oxide, and a layer of single crystal III-N semiconductor material deposited on the rare earth oxide structure. The rare earth oxide has a dielectric constant greater (close to or approximately two times greater) than the III-N semiconductor material. Source, gate, and drain terminals are formed on the layer of single crystal III-N semiconductor material with the gate terminal being positioned between the source and drain terminals and spaced from the drain terminal a distance providing a selected breakdown voltage. The at least one layer of single crystal rare earth oxide is selected to cooperate with the layer of single crystal III-N semiconductor material to reduce the thickness of the layer of single crystal III-N semiconductor material required for the selected breakdown voltage to a value less than a thickness of the layer of single crystal III-N semiconductor material for the selected breakdown voltage without the cooperating at least one layer of single crystal rare earth oxide.

The desired objects and aspects of the instant invention are further realized in accordance with a method of fabricating a III-N on silicon substrate with a selected breakdown voltage including the steps of selecting a breakdown voltage for the wafer, providing a crystalline silicon substrate, and depositing a rare earth oxide structure on the silicon substrate. The oxide structure includes at least one layer of single crystal rare earth oxide. The method further includes the step of depositing a layer of single crystal III-N semiconductor material on the rare earth oxide structure, the rare earth oxide having a dielectric constant greater (close to or approximately two times greater) than the III-N semiconductor material. The method further includes the step of selecting the at least one layer of single crystal rare earth oxide to cooperate with the layer of single crystal III-N semiconductor material to reduce the thickness of the layer of single crystal III-N semiconductor material required for the selected breakdown voltage to a value less than a thickness of the layer of single crystal III-N semiconductor material for the selected breakdown voltage without the cooperating at least one layer of single crystal rare earth oxide.

### BRIEF DESCRIPTION OF THE DRAWING

The foregoing and further and more specific objects and advantages of the instant invention will become readily apparent to those skilled in the art from the following detailed description of a preferred embodiment thereof taken in conjunction with the drawings, in which:

FIG. 1 is a schematic diagram of a field effect transistor on a III-N on silicon substrate or a semiconductor-on-insulator (SOI) substrate in accordance with the present invention;

FIG. 2 diagrammatically illustrates the relationship between mesa separation and breakdown voltage for the field effect transistor of FIG. 1;

FIG. 3 is an equivalent circuit diagram (equivalent resistor network) for the field effect transistor of FIG. 1;

FIG. 4 is a simplified equivalent diagram for two possible breakdown conditions using the equivalent circuit diagram of FIG. 3; and

FIG. 5 illustrates the effect of adding rare earth oxide in the total path contribution of FIG. 3.

### DETAILED DESCRIPTION OF THE DRAWINGS

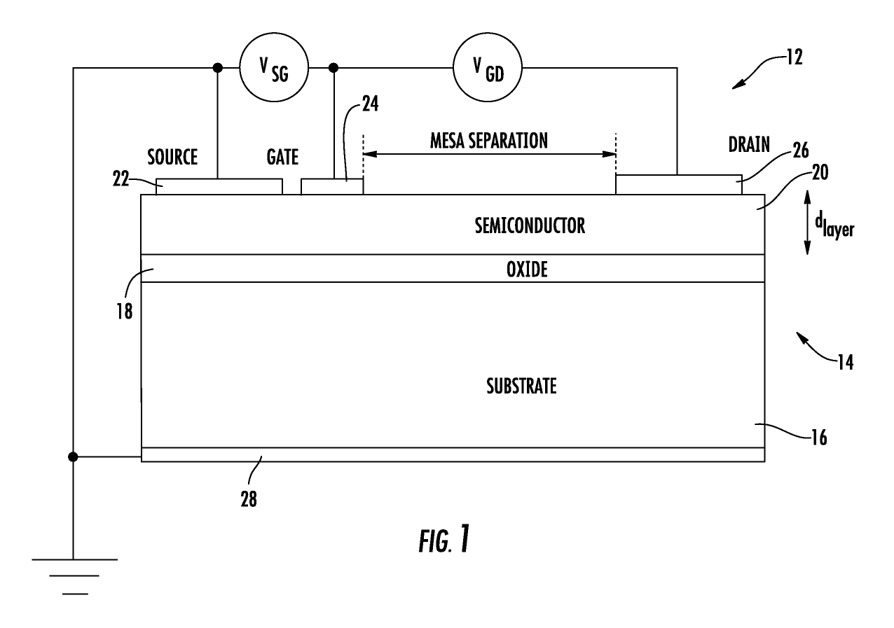

Referring to FIG. 1, a field effect transistor 12 on an SOI substrate structure 14, in accordance with the present invention, is illustrated. Generally, structure 14 includes a silicon substrate 16 with a structure 18 of rare earth oxide (REO) and a III-N semiconductor layer 20 on top of structure 18. Substrate 16 includes a single crystal silicon which, it will be understood, is or may be a standard well know single crystal silicon wafer or portion thereof generally known and used in the semiconductor industry. Single crystal silicon substrate 16, it will be understood, is not limited to any specific crystal orientation but could include <111> silicon, <110> silicon, <100> silicon or any other orientation or variation known and used in the art.

Rare earth oxide structure 18 is grown directly on the surface of substrate 16 using any of the well known growth methods, such as MBE, MOCVD, PLD (pulsed laser deposition), sputtering, ALD (atomic layer deposition), or any other known growth method for thin films. Further, the growth method used will generally be used for all additional layers and may conveniently be employed to grow the entire structure in a continuous process sometimes referred to herein as performed within a one wafer single epitaxial process. Rare earth oxide structure 18 may be considered a single layer, a plurality of single crystal or crystalline layers, or a single layer of single crystal or crystalline material with a plurality of sub-layers, any of which will be referred to herein for convenience of understanding as a “rare earth oxide structure”. Further, rare earth oxide structure 18 may vary from the bottom to the top and/or within each layer either linearly or in a step by step process. In any case, rare earth oxide structure 18 is positioned between the surface of substrate 16 and the lower surface of single crystal semiconductor layer 20. Generally, layer 20 will include a III-N material which is defined as a nitride of any of the metals from the III group in the periodic table or combinations thereof. In a preferred embodiment, the III-N material is GaN. Also, throughout this disclosure whenever rare earth materials are mentioned it will be understood that “rare earth” materials are generally defined as any of the lanthanides as well as scandium and yttrium.

Rare earth oxide structure 18 may be specifically designed or engineered to gradually adjust from the crystal lattice of substrate 16 to approximately the crystal lattice of the III-N semiconductor layer 20. This gradual adjustment of the crystal lattice between the interface with substrate 16 and the interface with layer 20 is generally designed to closely or approximately match the lattice spacing between adjacent layers or to provide a predetermined amount of stress or mismatch in lattice spacing to compensate for cracking and/or bowing in layer 20. Rare earth oxide structure 18 may be gradually adjusted from the crystal lattice of substrate 16 to approximately the crystal lattice of the III-nitride semiconductor layer 20 so that a thicker layer 20 can be grown with no cracking and/or bowing.

Field effect transistor 12 fabricated on semiconductor layer 20 includes a source 22, a gate 24, and a drain 26. Gate 24 and drain 26 are spaced apart a distance designated ‘mesa separation’. Also voltages or signals applied between source 22 and gate 24 and between gate 24 and drain 26 are designated V_{SG} and V_{GD}, respectively. A metal contact 28 is deposited on the rear surface of substrate 16 and is grounded, as well as being connected to source 22, which connection may be intentional, through direct connection, or the result of packaging.

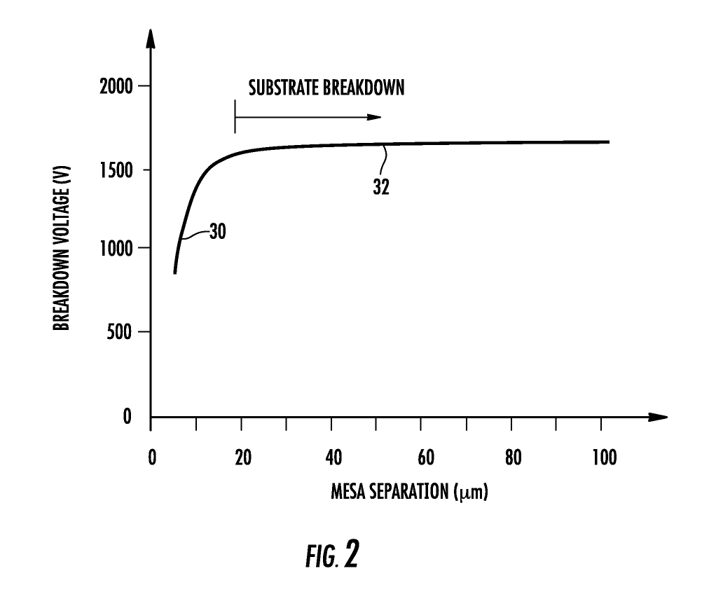

Referring additionally to FIG. 2, the relationship between mesa separation and breakdown voltage for field effect transistor 12 is diagrammatically illustrated. In this explanation, the gate voltage is assumed to be negligible, i.e. V_{GD}>>V_{SG}. The graph of FIG. 2 shows that the breakdown voltage saturates above a certain level (above approximately 1700 volts in this example) and mesa separation has very little or no effect thereafter. Generally, the graph of FIG. 2 has two parts, a low voltage region (i.e. sloping portion 30) where the breakdown voltage of the semiconductor layer 20 R_{GateDrain} dominates and a higher voltage (i.e. flat portion 32) where the breakdown voltage through substrate 16 dominates.

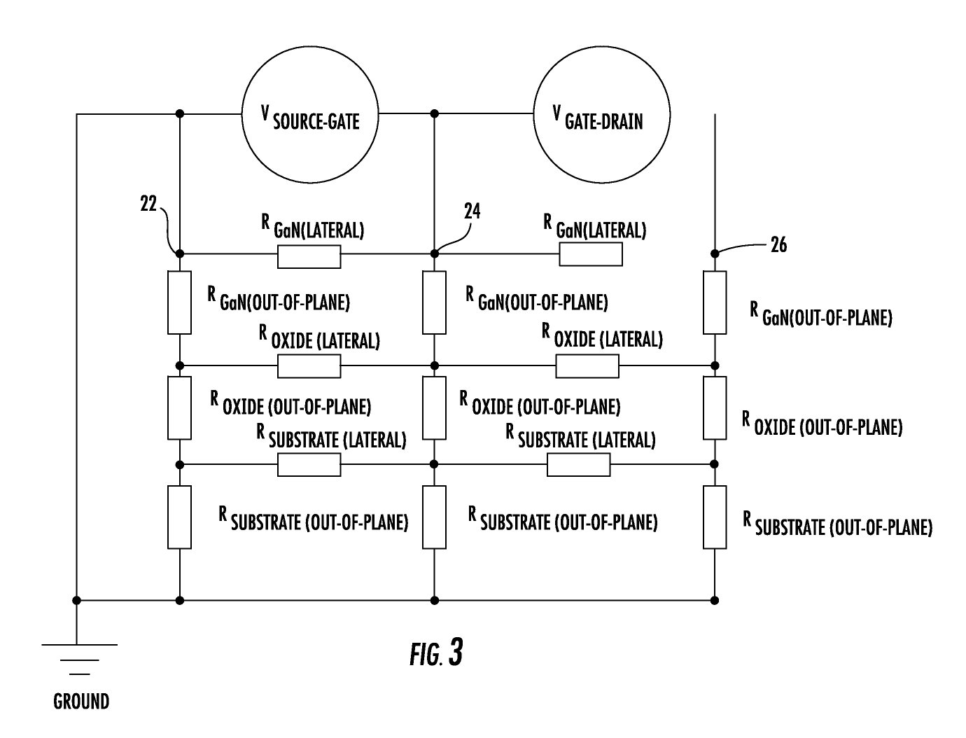

Turning to FIG. 3, an equivalent resistor network diagram for field effect transistor 12 on SOI substrate structure 14 of FIG. 1 is illustrated. In this diagram, for convenience of understanding, source 22, gate 24, and drain 26 are shown as potential or voltage points. The resistance laterally (horizontally through each of the layers) between potential points and the resistance out-of-plane (vertically through each of the layers) between potential points and ground are illustrated for each layer of substrate structure 14.

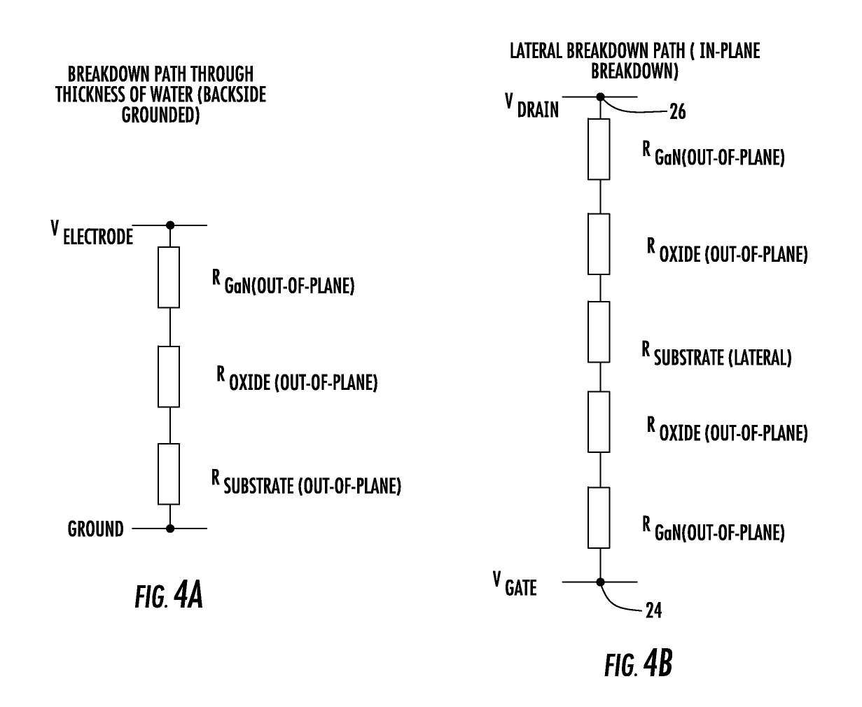

Referring additionally to FIG. 4, two different breakdown paths through the equivalent resistor network diagram of FIG. 3 are illustrated and designated a) and b). An alternative configuration is with no metallization on the back of the substrate which is then not grounded. Breakdown path a) illustrates the breakdown path through the thickness of substrate structure 14 from any of the potential points 22, 24, and 26 to ground (metal contact 28 in FIG. 1). In each case the total breakdown resistance is the out-of-plane resistance of semiconductor layer 20 plus the out-of-plane resistance of oxide layer 18 plus the out-of-plane resistance of substrate 16.

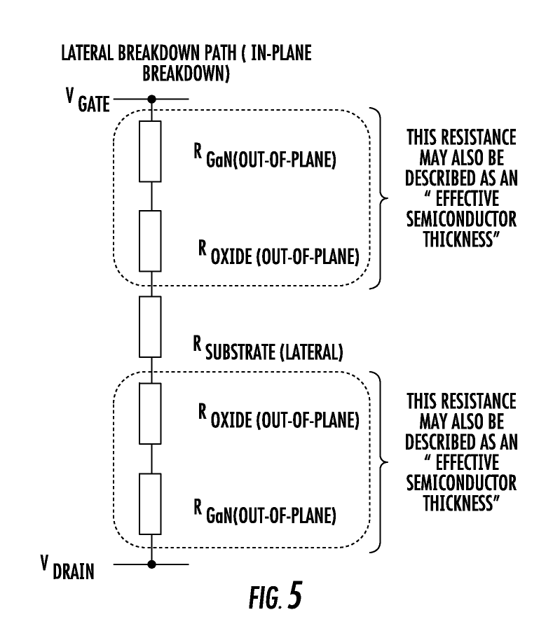

Breakdown path b) illustrates the breakdown path laterally (in-plane breakdown) from the drain potential point 26 to the gate potential point 24. This illustrates a breakdown mechanism which is true whether or not the back of the substrate is grounded. As illustrated in FIG. 4 b), the lateral breakdown path from drain 26 to gate 24 is the out-of-plane resistance of semiconductor layer 20 plus the out-of-plane resistance of oxide layer 18 plus the lateral resistance of substrate 16 plus the out-of-plane resistance of oxide layer 18 plus the out-of-plane resistance of semiconductor layer 20. As illustrated in FIG. 5, the out-of-plane resistance of semiconductor layer 20 plus the out-of-plane resistance of oxide layer 18 from the gate 24 can be described as an “effective semiconductor thickness”. Similarly, the out-of-plane resistance of semiconductor layer 20 plus the out-of-plane resistance of oxide layer 18 from the drain 26 can be described as an “effective semiconductor thickness”.

To further explain the concept and using specific materials in an example: the breakdown of silicon is 3×10⁵ V/cm; the breakdown of gallium nitride is 5×10⁶ V/cm; and the breakdown of rare earth oxide (generally any of the REOs described above) is 3×10⁶ V/cm. Also, the permittivity or dielectric constants of the examples are: silicon (∈_{silicon}) is 11.7; gallium nitride (∈_{GaN}) is 8.0; and rare earth oxide (∈_{REO}) is approximately 17. The rare earth oxide permittivity is approximately twice that of the gallium nitride, consequently the field within the material is lower which improves the electric field screening and breakdown characteristics of a film of a given thickness. That is, because the out-of-plane resistance of semiconductor layer 20 plus the out-of-plane resistance of oxide layer 18 form an effective semiconductor thickness, the actual thickness of semiconductor layer 20 can be substantially reduced while maintaining a desired breakdown voltage.

As stated above, mechanically thick III-N on a silicon substrate is a challenge since the III-N layer tends to crack and the induced wafer bow can make it very difficult to process the wafer. One object of the present invention is to fix the III-N layer thickness at approximately 4 μm or less, a thickness that is relatively easy to achieve. Using a relatively high k REO layer, i.e. ∈_{REO}>>∈_{GaN} or close to or approximately twice as high, much higher breakdown voltages can be achieved. Thus, it can be seen that the layer of single crystal rare earth oxide can be selected to cooperate with the layer of single crystal III-N semiconductor material to reduce the thickness of the layer of single crystal III-N semiconductor material required for a selected breakdown voltage to a value less than a thickness of the layer of single crystal III-N semiconductor material for the selected breakdown voltage without the cooperating layer of single crystal rare earth oxide. That is, for a selected breakdown voltage a much thinner layer of III-N semiconductor material can be produce from the combination of rare earth oxide and III-N semiconductor material than can be produced from the III-N semiconductor material by itself.

Thus, in the present invention one of the advantages achieved is to be able to grow a thinner layer of III-N for a selected breakdown because of the field suppression characteristics of rare earth oxide structure 18. This feature is clearly shown in the above specific examples. Further, the REO layer can be “strain engineered”, i.e. the composition of the REO layer can be varied in order to control the strain in the III-N layer and allow thicker layers to be grown. Thus, the high k REO that provides the stand-off voltage benefits can lessen the detrimental effects of stress in the III-N layer and, hence, wafer cracking and bow. Because of the benefits of the high k REO layer, III-N layers of approximately 4 μm or less can easily be deposited with little or no cracking and induced wafer bowing.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A III-N on silicon substrate with enhanced breakdown voltage comprising:
a crystalline silicon substrate;
a rare earth oxide structure deposited on the silicon substrate and including at least one layer of single crystal rare earth oxide; and
a layer of single crystal III-N semiconductor material deposited on the rare earth oxide structure, the at least one layer of single crystal rare earth oxide having a dielectric constant greater than the III-N semiconductor material, and the rare earth oxide structure being selected to cooperate with the layer of single crystal III-N semiconductor material to reduce the thickness of the layer of single crystal III-N semiconductor material required for a selected breakdown voltage to a value less than a thickness of the layer of single crystal III-N semiconductor material for the selected breakdown voltage without the cooperating rare earth oxide structure.

2. A III-N on silicon substrate with enhanced breakdown voltage as claimed in claim 1 wherein the rare earth oxide structure is strain engineered to approximately crystal lattice match the layer of III-N semiconductor material, whereby deformations in the layer of III-N semiconductor material are substantially eliminated.

3. A III-N on silicon substrate with enhanced breakdown voltage as claimed in claim 1 wherein the rare earth in the rare earth oxide structure includes at least one of the lanthanides, scandium and yttrium.

4. A III-N on silicon substrate with enhanced breakdown voltage as claimed in claim 1 wherein the III material in the III-N semiconductor material is a metal selected from the III group in the periodic table.

5. A III-N on silicon substrate with enhanced breakdown voltage as claimed in claim 1 wherein the thickness of the layer of single crystal III-N semiconductor material is in a range of 8 μm or less.

6. A III-N on silicon substrate with enhanced breakdown voltage as claimed in claim 1 wherein the single crystal III-N semiconductor material includes GaN.

7. A III-N on silicon substrate with enhanced breakdown voltage as claimed in claim 1 wherein the rare earth oxide structure includes Gd₂O₃.

8. A III-N on silicon substrate with enhanced breakdown voltage as claimed in claim 1 wherein the at least one layer of single crystal rare earth oxide has a dielectric constant approximately twice the dielectric constant of the III-N semiconductor material.

9. A III-N on silicon substrate with enhanced breakdown voltage comprising:
a crystalline silicon substrate;
a rare earth oxide structure deposited on the silicon substrate and including at least one layer of single crystal rare earth oxide; and
a layer of single crystal III-N semiconductor material deposited on the rare earth oxide structure, the at least one layer of single crystal rare earth oxide having a dielectric constant greater than the III-N semiconductor material, and the rare earth oxide structure being selected to cooperate with the layer of single crystal III-N semiconductor material to reduce the thickness of the layer of single crystal III-N semiconductor material to within a range of approximately 8 μm or less to achieve higher breakdown voltage than possible using the III-N semiconductor alone.

10. A field effect transistor fabricated in a III-N on silicon substrate with enhanced breakdown voltage comprising:
a crystalline silicon substrate;
a rare earth oxide structure deposited on the silicon substrate and including at least one layer of single crystal rare earth oxide;
a layer of single crystal III-N semiconductor material deposited on the rare earth oxide structure, the at least one layer of single crystal rare earth oxide having a dielectric constant greater than the III-N semiconductor material; and
source, gate, and drain terminals formed on the layer of single crystal III-N semiconductor material, the gate terminal being positioned between the source and drain terminals and spaced from the drain terminal a distance providing a selected breakdown voltage, and the rare earth oxide structure being selected to cooperate with the layer of single crystal III-N semiconductor material to reduce the thickness of the layer of single crystal III-N semiconductor material required for the selected breakdown voltage to a value less than a thickness of the layer of single crystal III-N semiconductor material for the selected breakdown voltage without the cooperating rare earth oxide structure.

11. A field effect transistor as claimed in claim 9 wherein the thickness of the layer of single crystal III-N semiconductor material is in a range of 8 μm or less.

12. A field effect transistor as claimed in claim 9 wherein the single crystal III-N semiconductor material includes GaN.

13. A field effect transistor as claimed in claim 9 wherein the rare earth oxide structure includes Gd₂O₃.

14. A method of fabricating a III-N on silicon substrate with a selected breakdown voltage comprising the steps of:
selecting a breakdown voltage;
providing a crystalline silicon substrate;
depositing a rare earth oxide structure on the silicon substrate, the oxide structure including at least one layer of single crystal rare earth oxide; and
depositing a layer of single crystal III-N semiconductor material on the rare earth oxide structure, the at least one layer of single crystal rare earth oxide having a dielectric constant greater than the III-N semiconductor material, and selecting the rare earth oxide structure to cooperate with the layer of single crystal III-N semiconductor material to reduce the thickness of the layer of single crystal III-N semiconductor material required for the selected breakdown voltage to a value less than a thickness of the layer of single crystal III-N semiconductor material for the selected breakdown voltage without the cooperating rare earth oxide structure.

15. A method as claimed in claim 14 wherein the step of depositing the layer of single crystal III-N semiconductor material includes depositing a layer with a thickness in a range of 8 μm or less.

16. A method as claimed in claim 14 wherein the step of depositing the layer of single crystal III-N semiconductor material includes depositing a layer of GaN.

17. A method as claimed in claim 14 wherein the step of depositing the rare earth oxide structure includes depositing at least one layer of Gd₂O₃.

18. A method as claimed in claim 14 wherein the step of depositing the rare earth oxide structure includes strain engineering the oxide structure to approximately crystal lattice match the layer of III-N semiconductor material, whereby deformations in the layer of III-N semiconductor material are substantially eliminated.

19. A method as claimed in claim 14 wherein the step of depositing the at least one layer of single crystal rare earth oxide includes depositing a single crystal rare earth oxide with a dielectric constant approximately twice the dielectric constant of the III-N semiconductor material.

20. A method of fabricating a III-N on silicon substrate with a selected breakdown voltage comprising the steps of:
selecting a breakdown voltage equal to or less than 3000 volts;
providing a crystalline silicon substrate;
depositing a rare earth oxide structure on the silicon substrate, the oxide structure including at least one layer of single crystal rare earth oxide; and
depositing a layer of single crystal III-N semiconductor material on the rare earth oxide structure, the at least one layer of single crystal rare earth oxide having a dielectric constant greater than the III-N semiconductor material, and the rare earth oxide structure being selected to cooperate with the layer of single crystal III-N semiconductor material to reduce the thickness of the layer of single crystal III-N semiconductor material to within a range of approximately 5 μm or less.

21. A method as claimed in claim 20 wherein the step of depositing the layer of single crystal III-N semiconductor material includes depositing a layer of GaN.

22. A method as claimed in claim 20 wherein the step of depositing the rare earth oxide structure includes depositing at least one layer of Gd₂O₃.

23. A method as claimed in claim 20 wherein the step of depositing the rare earth oxide structure includes strain engineering the oxide structure to approximately crystal lattice match the layer of III-N semiconductor material, whereby deformations in the layer of III-N semiconductor material are substantially eliminated.
